(19) United States
(12) Patent Application Publication
(10) Pub. No.: US 2007/0255999 A1
(43) Pub. Date: Nov. 1, 2007

(54) Memory Arrangement And Method For Error Correction

(75) Inventor: Gerhard Risse, Munchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Munchen (DE)

(21) Appl. No.: 11/696,745

(22) Filed: Apr. 5, 2007

(30) Foreign Application Priority Data
Apr. 7, 2006 (DE) 10 2006 016 499.7

(51) Int. Cl. G11C 29/00

(52) U.S. Cl. 714/766

(57) ABSTRACT

A method of error correction for a memory arrangement includes dividing information to be written to the memory arrangement into n data blocks of m bits each, writing the n data blocks to at least one memory module of the memory arrangement, determining a redundant data block based on the n data blocks, writing the redundant data block to a further memory module of the memory arrangement, reading the n data blocks, and checking for errors in the read n data blocks including detecting a faulty data block in the read n data blocks. If an error is detected, the method includes reading the redundant information in advance from the at least one further memory module and determining all bits of the faulty data block from the n data blocks and the redundant data block.

### CROSS-REFERENCE TO RELATED APPLICATIONS

This Utility Patent Application claims priority to German Patent Application No. DE 10 2006 016 499.7, filed on Apr. 7, 2006, which is incorporated herein by reference.

### BACKGROUND

Memory modules such as, for example, fully buffered dual inline memory modules (DIMMs) have conventionally no built-in redundancy in relation to errors in their memory chips that go beyond the error correction options of an error checking and correction (ECC) code. For error correction via an ECC code, redundant bits are typically generated via the ECC code starting out from the bits of specified information to be stored and the redundant bits are stored together with the specified bits. On read-out it is then checked via of the ECC code whether errors have occurred during storage or read-out, the errors either being corrected or just detected depending on the seriousness of the error and on the proportion of redundant bits to total bits stored.

Furthermore, memory modules exist that mirror each bit to be stored or store it twice to avoid errors. However, this method disadvantageously results in an increase in the bandwidth and memory capacity employed of 100%. Moreover, this method cannot be adapted to an error susceptibility of a memory module or to a desired reliability standard.

For these and other reasons, there is a need for the present invention.

### SUMMARY

One embodiment provides a method of error correction for a memory arrangement including dividing information to be written to the memory arrangement into n data blocks of m bits each, writing the n data blocks to at least one memory module of the memory arrangement, determining a redundant data block based on the n data blocks, writing the redundant data block to a further memory module of the memory arrangement, reading the n data blocks, and checking for errors in the read n data blocks including detecting a faulty data block in the read n data blocks. If an error is detected, the method includes reading the redundant information in advance from the at least one further memory module and determining all bits of the faulty data block from the n data blocks and the redundant data block.

### BRIEF DESCRIPTION OF THE DRAWINGS

The accompanying drawings are included to provide a further understanding of the present invention and are incorporated in and constitute a part of this specification. The drawings illustrate embodiments and together with the description serve to explain the principles of the embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates an embodiment of a memory arrangement with four memory modules.

FIG. 2A illustrates schematically how information is stored in a memory arrangement according to embodiment.

FIG. 2B illustrates schematically how a redundant data block is calculated from n data blocks according to an embodiment.

FIG. 3 illustrates schematically how information that contains no errors is read from a memory arrangement according to an embodiment.

FIG. 4A illustrates schematically how information that has a correctable error according to an embodiment is read from a memory arrangement according to an embodiment.

FIG. 4B illustrates schematically how all bits of a faulty data block are calculated from an error-free data block and the redundant data block according to an embodiment.

FIG. 5 illustrates a memory module controller according to an embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,”“bottom,”“front,”“back,”“leading,”“trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is also to be understood that in the following description of exemplary embodiments any direct connection or coupling between functional blocks, devices, components or other physical or functional units illustrated in the drawings or described herein could also be implemented by an indirect connection or coupling.

It is also to be understood that the features of various exemplary embodiments described herein may be combined with each other unless specifically noted otherwise.

Embodiments relate to a method for error correction for a memory arrangement as well as a correspondingly configured memory module controller, memory controller, and memory arrangement.

A method embodiment provides error correction for a memory arrangement. In this method embodiment, information to be written to the memory arrangement is divided up into n data blocks of m bits each. These n data blocks are stored in one or more memory modules of the memory arrangement, in particular n memory modules being present and each of the n data blocks being stored in a different one of these n memory modules. The division of information into n data blocks, which are stored in n different memory modules, functions by analogy with “data stripping”or redundant array of inexpensive disks (RAID) 0 from the field of hard disk management. In addition, redundant information, in particular k redundant data blocks likewise of m bits each, is determined on the basis of the n data blocks. In addition to the n data blocks, this redundant information is stored in one or more further memory modules of the memory arrangement, in particular k further memory modules being present and each of the k redundant data blocks being stored in a different one of these k further memory modules. Here the memory modules and the further memory modules can be the same memory modules, in an extreme case all n data blocks and the redundant information can be stored in the same memory module. In an embodiment, though, different memory modules are involved, i.e. the memory arrangement has n+k memory modules and the n data blocks and the k redundant data blocks are stored respectively in a different one of these n+k memory modules. In this case, that it is known which n data blocks form a unit with which redundant information, so that this unit can be found again and read out. When reading out the information, the n data blocks are read out and checked for errors, for example via the ECC code. This means that it is checked whether an error exists that cannot be corrected by means of the ECC code, for example. If an error that cannot be corrected exists or if p faulty data blocks are detected, the redundant information belonging to the n data blocks is read and on the basis of the n at least partially faulty data blocks, in particular the n-p error-free data blocks, and the redundant information, all bits of the p faulty data blocks are determined correctly. Then the n data blocks that have possibly been corrected are output.

In making it possible to select freely a ratio between a magnitude of redundant information, in particular the number k of redundant data blocks, and the number n of data blocks that form the information to be stored, the method according to the invention for error correction offers on the one hand the option of correcting errors without at the same time increasing the bandwidth and the memory capacity by 100%, and on the other hand the reliability of a memory arrangement in which the method according to an embodiment is used can be set virtually arbitrarily in that the ratio between the magnitude or quantity of redundant information and the number n is adjusted accordingly.

Several items of information can be written to the memory arrangement by dividing them up respectively into n data blocks, and that these items of information can then be read out from the memory arrangement again in any order.

In an embodiment , k redundant bits are determined for each bit position within the k redundant data blocks on the basis of the n bits of the n data blocks to be written. Expressed in another way, the quantity of k bits for a defined bit position of the k redundant data blocks is determined starting out from the quantity of n bits that are present at this defined bit position in the case of the n data blocks to be written.

In that k bits are determined respectively only on the basis of n bits, a simple coding method or a simple coding device, for example one including few logic gates, can be used to determine the k bits on the basis of the n bits. Thus the k redundant data blocks can be determined using simple means and thus cost-effectively according to embodiments.

In an embodiment, k=1, so that only one redundant data block is formed from the n data blocks. Here each bit of this redundant data block is formed by linking the n bits at the bit position within the n data blocks corresponding to the bit to be formed by means of an XOR function. When the n data blocks are read out, a faulty data block can then be corrected by determining each bit of this faulty data block in that the n−1 bits at the bit position corresponding to the bit to be determined within the n−1 error-free data blocks are linked via an XOR function to the bit at the bit position corresponding to the bit to be formed within the redundant data block.

A memory module controller for a memory module is also provided according to an embodiment. The memory module controller embodiment is configured such that on receipt of a command, which addresses an address within the memory module assigned to the memory module controller, it reads from memory chips of this memory module a data block that is stored at this address and outputs it via output connections of the memory module controller. Furthermore, the memory module controller embodiment temporarily stores n data blocks of m bits each in an intermediate storage device. Starting out from these n data blocks, a coding device of the memory module controller determines a redundant data block with m bits and stores this redundant data block in the memory chips. In one embodiment, he coding device advantageously then only determines the redundant data block if new n data blocks are present in the intermediate storage device. Expressed in another way, the memory module controller embodiment replaces the oldest data block in the intermediate storage device in each case with a new data block received by the memory module controller and only once all data blocks in the intermediate storage device have been replaced is the coding device instructed, starting out from these n data blocks newly stored temporarily, to produce a new redundant data block, which is then stored at an address with the aid of which it can be assigned to the n data blocks momentarily located in the intermediate storage device.

The reliability of a memory arrangement embodiment that comprises one or more memory modules with a memory module controller according to embodiments can be improved almost arbitrarily (the more memory modules with the memory module controller according to embodiments, the more reliable) without a controller of the memory arrangement having to activate the memory module controllers according to embodiments additionally when writing data to the memory arrangement. In other words, the controller of the memory arrangement does not have to take the memory module controllers according to embodiments into account when writing data, as these exhibit the behavior described above quasi automatically to generate redundant data blocks.

An embodiment of the memory module controller can be configured such that it does not store any data blocks temporarily and never generates a redundant data block. In other words, the memory module controller embodiment can be configured such that it behaves like a normal memory module controller.

Being able to configure the memory module controller according to embodiments as a conventional memory module controller means that the memory module controller according to embodiments can advantageously also be used in memory arrangements that do not use the method according to embodiments for error correction. In addition, memory module controllers according to embodiments that are configurable in such a way can also be used in memory arrangements that use the method according to embodiments for error correction, such a memory arrangement, as executed below, comprising on the one hand normal memory modules or memory modules with a correspondingly configured memory module controller according to embodiments for storing the n data blocks (without generating a redundant data block) and on the other hand memory modules with a memory module controller according to embodiments for generating the k redundant data blocks.

In an embodiment of the memory module controller, a coding device of the memory module controller comprises m XOR gates with n inputs each. These n inputs of each XOR gate are acted upon by those bits that are located in the n data blocks at the same bit position. Thus each XOR gate calculates respectively the bit of this bit position within the redundant data block.

An embodiment provides a memory controller for a memory arrangement with a plurality of memory modules. The memory controller embodiment divides information to be written to the memory arrangement into n data blocks. Then the memory controller embodiment writes these n data blocks to one or more memory modules, in particular the memory controller writes each of the n data blocks to a different memory module. To read out the information, the memory controller embodiment reads these n data blocks from the corresponding memory modules. Then the memory controller embodiment checks, in particular with the aid of an ECC code, whether there are errors within the n data blocks. If the memory controller embodiment has detected p faulty data blocks among the n data blocks, it reads k redundant data blocks with m bits each from at least one memory module, in particular from k memory modules, which do not correspond to the memory modules containing the n data blocks. The memory controller embodiment determines the address of these k redundant data blocks in this case from the addresses or address of the n data blocks. On the basis of the n data blocks and the k redundant data blocks, all bits of the p faulty data blocks are determined correctly via a decoding device of the memory controller.

As already indicated before, memory controller embodiments do not substantially differ in the writing of data from a conventional memory controller that has no error correction option going beyond the ECC code. It is only when reading, and even then only if the memory controller detects an error that cannot be rectified by the ECC coding, for example, that the behavior of the memory controller according to embodiments differs from that of the conventional memory controller, in that the memory controller embodiment corrects the error. A clock frequency or a bandwidth of the memory controller according to embodiments is thereby advantageously not negatively influenced by the additional error correction option, but can have the same values as for example a comparable conventional memory controller.

A memory arrangement embodiment includes at least one memory module and a memory controller for controlling the at least one memory module. In this case, information transmitted by the memory controller to any of the memory modules is forwarded to all memory modules of the memory arrangement embodiment. Information to be written to the memory arrangement embodiment is divided up by the memory controller into n data blocks with m bits each and stored in the at least one memory module. At least one memory module of the memory arrangement embodiment is a redundant memory module, each of these at least one redundant memory modules temporarily storing these n data blocks, calculating redundant information, in particular a redundant data block with m bits, on the basis of these n data blocks and storing this information. In an embodiment, the memory arrangement comprises n memory modules for storing the n data blocks (one of the n data blocks is stored in each of the n memory modules) and k memory modules, which calculate and store a redundant data block respectively on the basis of the n data blocks or a subset of these n data blocks. The memory arrangement embodiment has a mechanism for assigning the redundant information or the k redundant data blocks to the corresponding n data blocks. On reading out the information, the memory arrangement embodiment reads the n data blocks and checks whether the n data blocks are faulty. If this is the case, the memory arrangement reads the redundant information from the at least one redundant memory module and determines from the n data blocks, in particular from error-free ones of these, and the redundant information the correct bits of faulty data blocks of the n data blocks.

Certain advantages of the memory arrangement according to embodiments substantially equate to the advantages described above in connection with the description of the method according to embodiments for error correction, the memory module controller or memory controller according to embodiments.

Embodiments are suitable for use in memory arrangements that comprise several memory modules, in particular fully buffered DIMMs, the memory arrangement using data stripping when writing information to the memory arrangement.

Embodiments are not restricted to the above-mentioned application area, but can be used, for example, even in a memory arrangement that comprises only one memory module.

Hereinafter, embodiments are described in more detail with reference to the drawings.

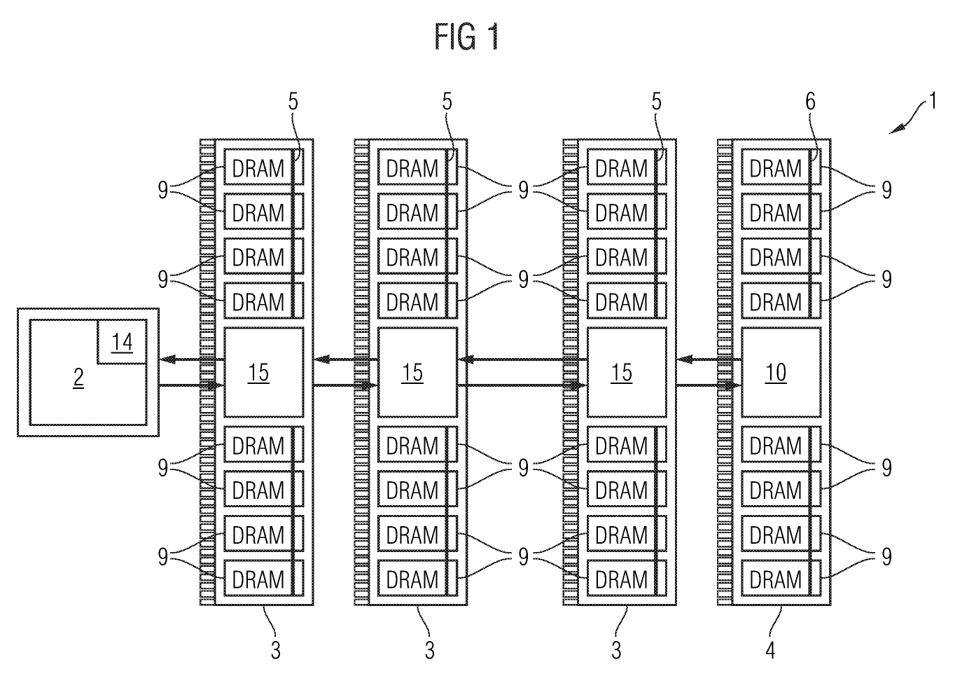

In FIG. 1, a memory arrangement 1 according to an embodiment is illustrated with a memory controller 2, three normal memory modules 3 and one redundant memory module 4. In this embodiment, the memory modules 3, 4 are connected to the memory controller 2 according to the daisy-chain principle. In the illustrated embodiment, each memory module 3, 4 comprises eight DRAMs 9 as memory chips. In one embodiment, each memory module 3, 4 is a fully buffered DIMM, meaning that incoming signals are completely stored temporarily and forwarded immediately, so that information transmitted by the memory controller 2 is present virtually simultaneously at all memory modules 3, 4. According to this embodiment, only following intermediate storage does the respective memory module analyze whether the information stored temporarily concerns it or not. If the information stored temporarily concerns the corresponding memory module, the information is processed accordingly and otherwise deleted.

According to this embodiment, if information is to be written to the memory arrangement 1, this information is divided up by the memory controller 2 into three data blocks, which are then stored respectively in a different one of the three normal memory modules 3 at respectively the same address, which has been assigned to the information. Since, as already described above, each memory module 3, 4 receives each item of information, the redundant memory module 4 also receives these three data blocks and stores them temporarily in a FIFO of its memory module controller 10. If the memory module controller 10 detects that three data blocks with the same address have been stored in its FIFO, a redundant data block 6 with m bits is calculated from these data blocks, as explained in detail below, and is stored in the redundant memory module 4 at the same address. Thus while a data block 5 with m bits is stored in each case in the three normal memory modules 3, a redundant data block 6 calculated from these three data blocks 5 is stored in the redundant memory module 4.

According to this embodiment, if the memory arrangement 1 is instructed to read out information stored beforehand, the memory controller 2 instructs the three normal memory modules 3 to each read out a data block 5 of an address corresponding to the information, i.e., the data block 5 of the same address is read out in each of the three normal memory modules 3. On read-out the memory controller 2 checks, as described below in detail, whether the data blocks read out by the three normal memory modules are correct. If the memory controller 2 detects that one of the data blocks read out has an error, it instructs the redundant memory module 4 to read out the corresponding redundant data block 6 by instructing the redundant memory module 4 to read out the data block 6 of the same address (at which the three data blocks were read out from the normal memory modules 3 also). In a decoding device 14 of the memory controller 2, the correct bits of the faulty data block are determined via the two correct data blocks and the redundant data block 6, as explained in detail below. The information requested by the memory arrangement 1 is then constructed from the three now correct data blocks 5 and transmitted to a requesting device.

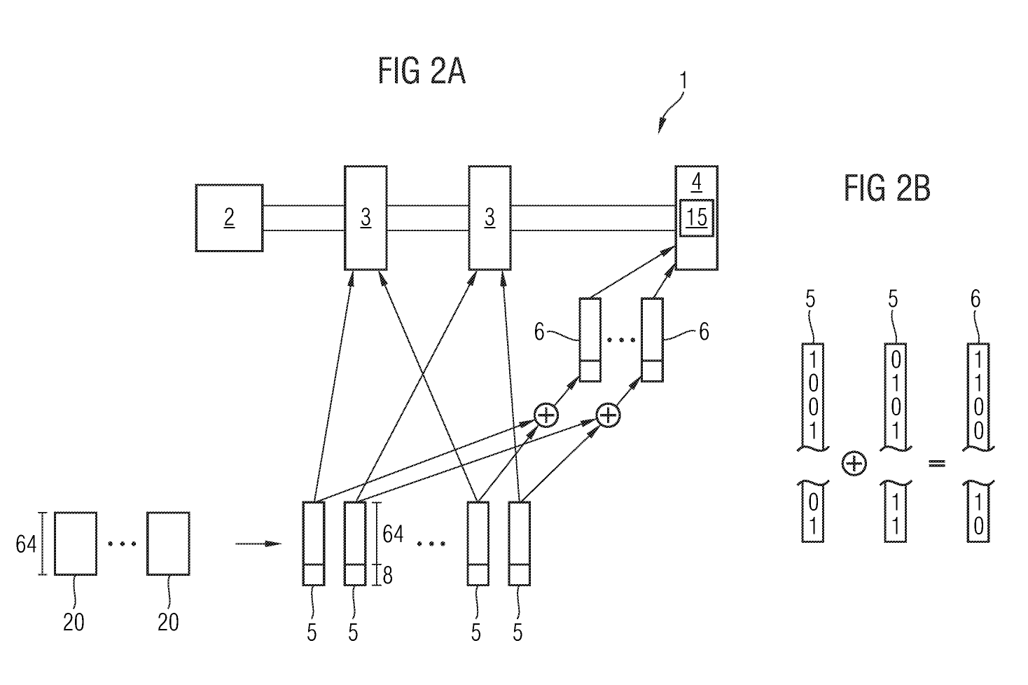

FIG. 2A illustrates schematically how a plurality of information 20 is written to the memory arrangement 1 according to an embodiment. For drawing reasons, however, the memory arrangement depicted in FIGS. 2 to 4 only includes two normal memory modules 3 instead of the three normal memory modules in FIG. 1. This means that information to be written to the memory arrangement 1 of FIGS. 2 to 4 is only divided into two data blocks 5, which are then written to one of the two normal memory modules 3 respectively. In the same manner, when information is being read out, only one data block 5 respectively is read from one of the two normal memory modules 3 in each case.

According to this embodiment, when information 20 to be written reaches the memory arrangement 1, this information 20 is divided up on the one hand with 64 bits in each case into two data blocks and on the other hand eight redundant (additional) bits are determined via an ECC code for each data block, which bits are added to the corresponding data block 5, so that each of the two data blocks 5 comprises 72 bits. Then the memory controller 2 instructs the first normal memory module 3 (on the left in FIG. 1) to store the first data block 5 (on the left in FIG. 1) at the address of the information 20. Since the memory modules 3, 4 are temporary-storage (fully buffered) DIMMs, this write command together with the first data block 5 and the address is also present at the redundant memory module 4. The memory module controller 15 of the redundant memory module 4 stores the first data block 5 in its FIFO, which can store two data blocks of 72 bits each. Then the memory controller instructs the second normal memory module (in FIG. 2 the second memory module from the left) to store the second data block 5 at the same address. The redundant memory module 4 again receives this write command too, which comprises the address and the second data block 5. The memory module controller 15 again stores the second data block 5 in its FIFO and detects that the FIFO is now completely filled with data blocks of the same address. The memory module controller 15 therefore instructs its XOR device, which consists of 72 XOR gates with two inputs each, to combine respectively two bits of the same bit position of the two data blocks 5 located in the FIFO by means of the XOR function, so that a redundant data block 6 of 72 bits arises therefrom, which is stored by the memory module controller 15 at the address corresponding to the information 20. An example of how a redundant data block 6 is calculated from two data blocks 5 by means of the 72 XOR gates can be found in FIG. 2B.

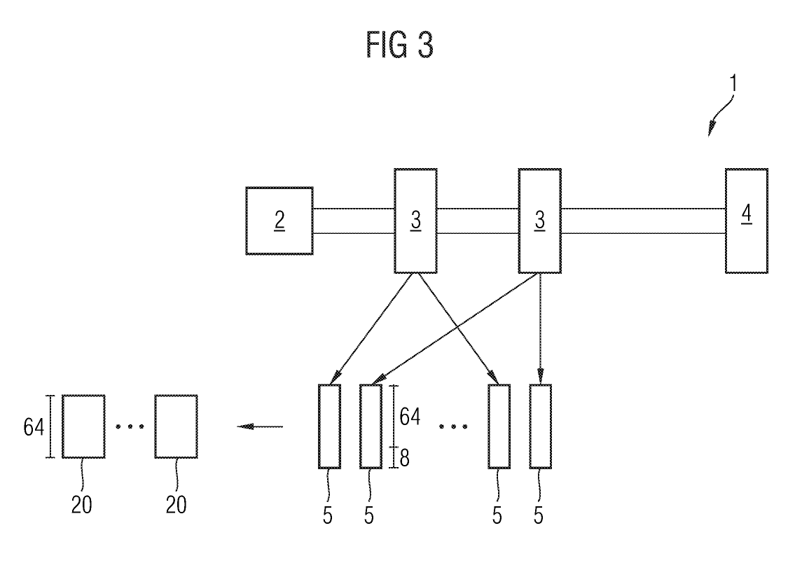

In FIG. 3 illustrates schematically how a plurality of information is read out from the memory arrangement 1 according to an embodiment. If the memory controller 2 is instructed to read out information 20 at a certain address, the memory controller 2 instructs the two normal memory modules 3 to each read a data block with 72 bits in each case from each of the two normal memory modules 3 at the certain address. The memory controller 2 then checks with the aid of the ECC code and the eight redundant bits located in each data block 5 whether the respective data block is correct or not. If, as assumed in FIG. 3, the two data blocks 5 are correct or have an error that can be corrected via the ECC code and the eight redundant bits, the memory controller 2 constructs the information 20 requested by cutting off the redundant bits of each data block 5 and forming the information requested from the remaining 2×64 bits and transmitting it to the requesting device.

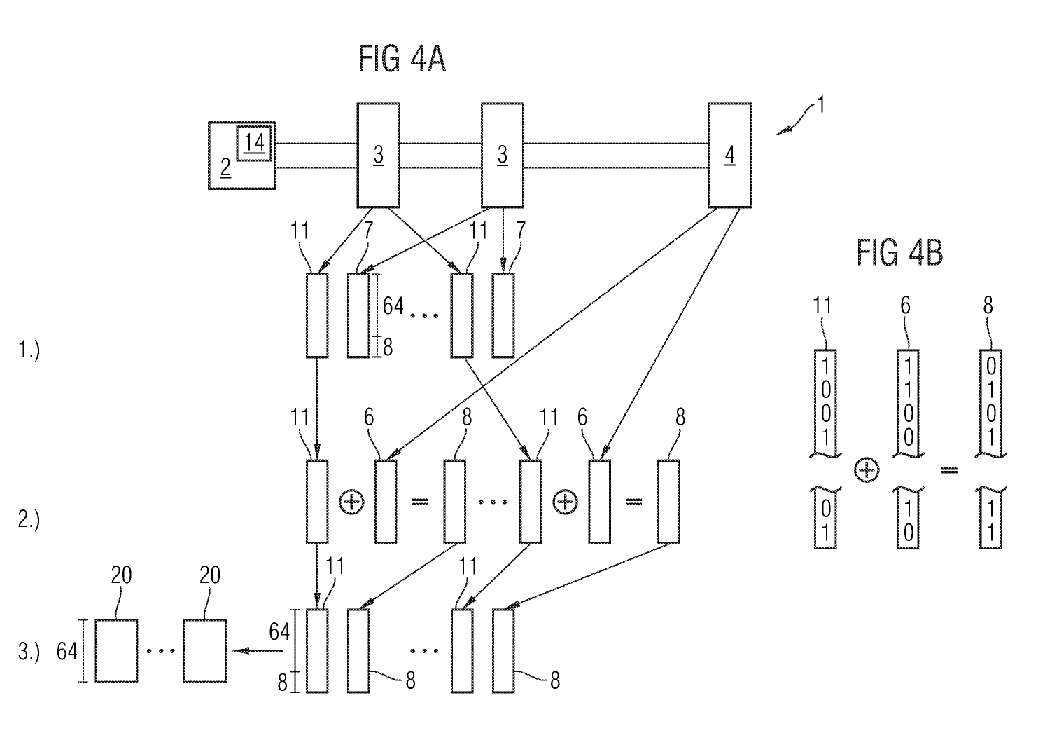

FIG. 4A schematically illustrates a case in which, on read-out of a plurality of information from the memory arrangement, an error that cannot be corrected via the ECC code and the eight redundant bits is detected by the memory controller 2 for each item of information according to an embodiment. As in FIG. 3, the memory controller 2 is instructed to read out information at a certain address.

According to this embodiment, to read out information 20, the memory controller 2 instructs both the first normal memory module and the second normal memory module to each read out a data block at the specified address. With reference to the ECC code and the eight redundant data bits, the memory controller 2 detects that the data block 7 of the second memory module 3 has an error that cannot be rectified by the ECC code together with the eight redundant bits.

According to this embodiment, in a second step the memory controller therefore instructs the redundant memory module 4 to read out the redundant data block 6 at the specified address (same address as the two data blocks). To determine the correct data block 8 or to correct the faulty data block 7 of the second memory module 3, a decoding device 14 of the memory controller 2 combines respectively two bits of the same bit position from the error-free data block 11 of the first memory module 3 and from the redundant data block 6 to one another by means of the XOR function. The 72 bits of the corrected data block 8 of the second memory module are the result. FIG. 4B, illustrates schematically by way of example how the corrected data block 8 is calculated on the basis of the bits of the error-free data block 11 and the bits of the redundant data block 6 according to this embodiment.

According to this embodiment, then the requested information 20 is formed by the memory controller 2 in a similar way as illustrated in FIG. 3 from the respective 64 non-redundant bits of the two data blocks 11, 8.

The bits of a corrected data block (such as, for example, the 72 bits of the corrected data block 8 in FIG. 4) can also be corrected via the ECC code.

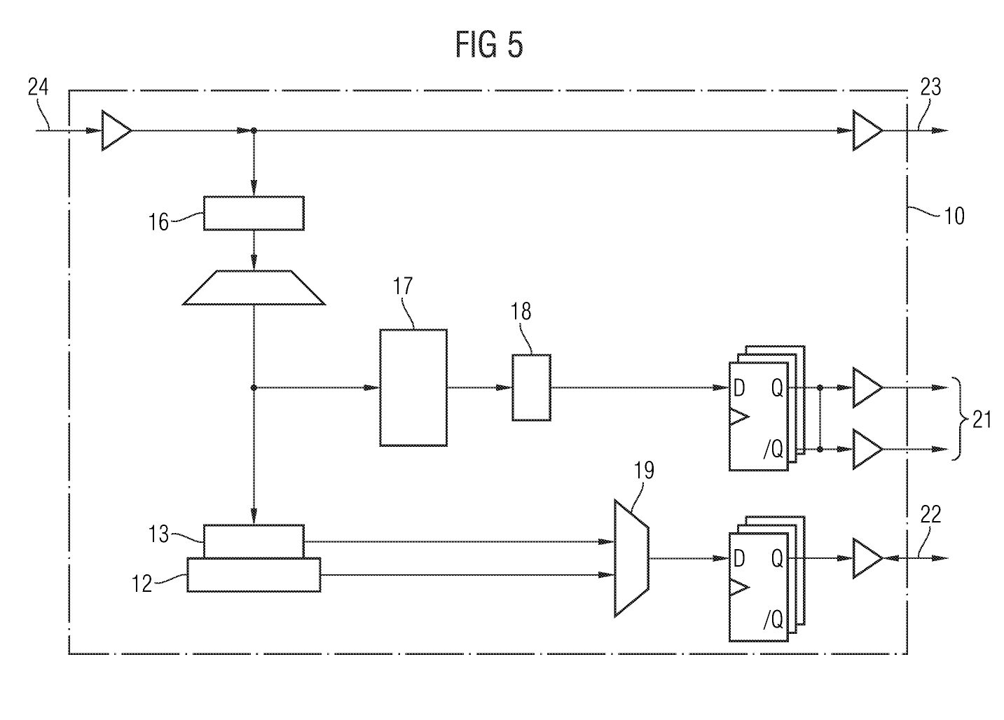

In FIG. 5 a memory module controller 10 according to an embodiment or an advanced memory buffer (AMB) is illustrated in detail, although only the devices of the memory module controller 10 that play a role in writing data blocks to the memory arrangement in which the memory module controller 10 according to the embodiment is used as illustrated.

According to this embodiment, a write command, which comprises a data block and an address, reaches the memory module controller at its terminal 24. The memory module controller 10 forwards this write command immediately via its terminal 23. Run-time differences are corrected via a device 16. Then the write command is evaluated by means of a command decoder 17 and a central control unit 18. If the command decoder 17 and the central controller 18 detect a write command, the corresponding data block is stored in the FIFO 13 of the memory module controller 10. The central control unit 18 checks whether all data blocks stored in the FIFO 13 belong to the same address. If this is the case, the redundant data block is calculated, as described before with the aid of FIG. 2, with the aid of 72 XOR gates, which have as many inputs as data blocks can be stored in the FIFO (three, therefore, for a memory module controller of the memory arrangement in FIG. 1 and two for a memory module controller of the memory arrangement in FIGS. 2 to 4). This data block is then stored via a multiplexer 19 and a data connection 22 in the memory chips assigned to the memory module controller 10 at the address to which the data blocks stored in the FIFO 13 belong. This address and related commands for the memory chips are communicated via a further connection 21 of the memory module controller 10 to the memory chips assigned to the memory module controller 10.

According to this embodiment, the FIFO 13 is configured such that when storing a new data block, it pushes out or deletes the oldest data block in each case. Since the memory arrangement 1 writes its data via data stripping, it is guaranteed that information is always written in units of n data blocks, which each have the same address, consecutively to the memory arrangement 1 and thus also to the memory module controller 10 of the redundant memory module 4, so that the memory module controller 10 only has to detect when n data blocks belonging to the same unit or n data blocks with the same address are present in its FIFO 13. Normally this is the case following every nth insertion of a data block into the FIFO 13.

According to this embodiment, if the memory module controller 10 is configured normally, i.e., if the memory module controller 10 is not configured for the generation of redundant data blocks, no data block is stored in the FIFO 13 on the one hand and on the other hand the upper connection to the multiplexer 19 in FIG. 5 is used to store data blocks in the memory chips assigned to the memory module controller 10. In practice a memory arrangement according to embodiments comprises eight (non-redundant) normal memory modules, so that information to be written or read out has 64 bytes (8×8 bits). Here the redundant memory module, which has a memory module controller 10 according to embodiments with a FIFO 13 with memory capacity for 64 bytes, is located furthest away from the memory controller 2 according to embodiments, as is also the case in the embodiments illustrated above.

In an embodiment that is not illustrated, eight normal memory modules 3, for example, are arranged together with the redundant memory module 4 and the memory controller according to an embodiment in the form of a ring. In this case too the redundant memory module 4 is arranged further from the memory controller 2 than each of the eight normal memory modules 3. Otherwise expressed, four of the eight normal memory modules 3 in each case lie in the ring between the redundant memory module and the memory controller, regardless of the direction.

In another embodiment, likewise not illustrated, the memory arrangement according to an embodient has a plurality of redundant memory modules 4, which however form and store a redundant data block only on the basis of a subset of the data blocks to be stored in the normal memory modules 3. If the memory arrangement according to the invention has eight normal memory modules 3 and two redundant memory modules 4, a first memory module controller 10 of the two redundant memory modules 4 is set up such that it stores the first four data blocks of information to be stored in the memory arrangement in its FIFO and stores a redundant data block from this in the first redundant memory module 4. A second memory module controller 10 is set up in a similar manner such that it stores the second four data blocks of the information to be stored in its FIFO and calculates a redundant data block therefrom and stores this in the second redundant memory module 4. Such a memory arrangement according to embodiments with two redundant memory modules for eight normal memory modules 3 has a higher reliability and an improved error correction possibility compared with a memory arrangement according to an embodiment with one redundant memory module 4 for eight normal memory modules 3, as both an error in a data block of the first four data blocks and at the same time an error in a data block of the second four data blocks can be corrected.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of error correction for a memory arrangement, the method comprising:
dividing information to be written to the memory arrangement into n data blocks of m bits each;
writing the n data blocks to at least one memory module of the memory arrangement;
determining redundant information based on the n data blocks;
writing the redundant information to at least one further memory module of the memory arrangement;
reading the n data blocks;
checking for errors in the read n data blocks including detecting p faulty data blocks in the read n data blocks; and
if an error is detected, reading the redundant information in advance from the at least one further memory module and determining all bits of the p faulty data blocks from the n data blocks and the redundant information.

2. The method according to claim 1, wherein the dividing includes generating q bits, via an ECC code, which form a subset of the m bits of the respective data block, wherein the checking and detecting faulty data blocks includes evaluating the q bits together with the m-q remaining bits during read-out of one of the data blocks.

3. The method according to claim 1, wherein k redundant data blocks of m bits each form the redundant information.

4. The method according to claim 3, determining k redundant bits for each bit position of the m bits within the n data blocks, via a coding function for n bits, which are arranged in the n data blocks at the respective bit position, to thereby provide k redundant data blocks of m bits each.

5. The method according to claim 3, wherein p=1 and k=1, and the method comprises:
determining each of the m bits of the redundant data block including, for each bit position of the m bits within the n data blocks, combining the n bits that are arranged in the n data blocks at the respective bit position, via a logical function, the result of the logical function producing a bit of the redundant data block at the corresponding bit position.

6. The method according to claim 5, wherein the logical function comprises an XOR function or an XNOR function.

7. The method according to claim 5, wherein during read-out, only if precisely one faulty data block has been detected, each bit of the faulty data block is determined as a correct bit in that for each bit position of the m bits within the n−1 error-free data blocks, the n−1 bits that are arranged at the respective bit position in the n−1 error-free data blocks are combined via the logical function to the bit of the redundant data block at the respective bit position, the result of the logical function producing the correct bit of the faulty data block at the corresponding bit position.

8. The method according to claim 1, wherein each of the at least one memory modules and each of the at least one further memory modules is a dual inline memory module (DIMM).

9. The method according to claim 8, wherein each DIMM is a fully buffered DIMM.

10. A method of error correction for a memory arrangement, the method comprising:
dividing information to be written to the memory arrangement into n data blocks of m bits each;
writing the n data blocks to at least one memory module of the memory arrangement;
determining a redundant data block based on the n data blocks;
writing the redundant data block to a further memory module of the memory arrangement;
reading the n data blocks;
checking for errors in the read n data blocks including detecting a faulty data block in the read n data blocks;
if an error is detected, reading the redundant information in advance from the at least one further memory module and determining all bits of the faulty data block from the n data blocks and the redundant data block; and
outputting n data blocks.

11. The method according to claim 10, wherein each of the m bits of the redundant data block is determined by, for each bit position of the m bits within the n data blocks, the n bits that are arranged in the n data blocks at the respective bit position are combined via a XOR or XNOR function, the result of the XOR or XNOR function producing a bit of the redundant data block at the corresponding bit position.

12. The method according to claim 11, wherein during read-out, only if one faulty data block has been detected, each bit of the faulty data block is determined as a correct bit in that for each bit position of the m bits within the n−1 error-free data blocks, the n−1 bits that are arranged at the respective bit position in the n×1 error-free data blocks are combined via the XOR or XNOR function to the bit of the redundant data block at the respective bit position, the result of the logical function producing the correct bit of the faulty data block at the corresponding bit position.

13. A memory module controller for a memory module, the memory module controller comprising:
logic configured to respond to a read command to read a data block, addressed by an address within the read command, from at least one memory chip assigned to the memory module controller;
at least one output terminal configured to output the data block;
logic configured to store n data blocks of m bits each temporarily in an intermediate storage device;
a coding device configured to generate a redundant data block with m bits based on the n data blocks; and
logic configured to store the redundant data block in the at least one memory chip assigned to the memory module controller.

14. The memory module controller according to claim 13, wherein the coding device comprises m XOR gates with n inputs each, the n inputs of each XOR gate being acted upon by n bits, which are arranged in the n data blocks at a respective bit position, so that each XOR gate determines respectively one of the bit positions within the redundant data block.

15. The memory module controller according to claim 13, wherein the memory module controller is a memory module controller for a fully buffered dual inline memory module (DIMM).

16. The memory module controller according to claim 13, comprising:
logic configured to forward data present at corresponding input terminals of the memory module controller on the one hand to corresponding output terminals of the memory module controller and on the other hand stores them temporarily in a buffer of the memory module controller, the memory module controller only continuing to store temporarily a data block contained in the data as one of the n data blocks if an address contained in the data meets a predetermined criterion.

17. The memory module controller according to claim 13, wherein the memory module controller is configured such that the coding device is configured to only generates the redundant data block and logic is configured to store the redundant data block if the memory module controller has temporarily stored the n data blocks.

18. The memory module controller according to claim 13, comprising logic configurable to not store any data blocks temporarily in the intermediate storage device and to not generate any redundant data block, and, on receipt of a write command, the address of which corresponds to the memory module controller, configured to write a data block assigned to the write command to at least one memory chip assigned to the memory module controller.

19. A memory controller for a memory arrangement comprising:
a plurality of memory modules;
means for dividing information to be written to the memory arrangement into n data blocks of m bits each;
means for writing the n data blocks to at least one memory module;
means for reading the n data blocks from the at least one memory module;
means for detecting faulty data blocks among the n data blocks;
means, responsive to the detection of p faulty data blocks, for reading k redundant data blocks of m bits each, which are assigned to the n data blocks, from at least one further memory module; and
means for determining all bits of the p faulty data blocks correctly on the basis of n-p error-free data blocks and the k redundant data blocks.

20. The memory controller according to claim 19, comprising:
means, on dividing up the information to be written, for generating q redundant bits for each of the n data blocks via an ECC code, which redundant bits form a subset of the m bits of the respective data block; and
means, on reading out each data block, for determining with reference to these q bits together with the m-q remaining bits of the respective data block whether the corresponding data block is faulty.

21. The memory controller according to claim 20, wherein p=1 and k=1, the means for determining all bits comprises means for determining all bits of the faulty data block correctly in that for each bit position of the m bits within n−1 error-free data blocks, n×1 bits that are arranged in the n×1 error-free data blocks at the respective bit position and a bit that is located at the respective bit position in the redundant data block are combined via an XOR function, the result of the XOR function producing a correct bit of the faulty data block at the respective bit position.

22. The memory controller according to claim 21, wherein means for determining all bits comprises m XOR gates with n inputs each, wherein the control device is configured such that the memory controller calculates with each XOR gate the correct bit that is located at the respective bit position in the faulty data block, and that the control device acts upon the n inputs of each XOR gate with the n−1 bits of the n−1 error-free data blocks at the respective bit position and with the bit of the redundant data block at the respective bit position.

23. A memory controller for a memory arrangement, the memory controller comprising:
a plurality of memory modules;
logic configured to divide information to be written to the memory arrangement into n data blocks of m bits each;
logic configured to write the n data blocks to at least one memory module;
logic configured to reads the n data blocks from the at least one memory module and, if the logic detects one faulty data block among the n data blocks, reads out one redundant data block of m bits, which is assigned to the n data blocks, from one further memory module; and
a decoding device configured to determines all bits of the faulty data block correctly based of n×1 error-free data blocks and the redundant data block.

24. The memory controller according to claim 23, wherein the decoding device comprises m XOR gates with n inputs each, wherein the control device is configured such that the memory controller with each XOR gate the correct bit is calculated that is located at the respective bit position in the faulty data block, and that the control device acts upon the n inputs of each XOR gate with the n−1 bits of the n−1 error-free data blocks at the respective bit position and with the bit of the redundant data block at the respective bit position.

25. A memory arrangement comprising:
at least one memory module;
at least one redundant memory module;
a memory controller for controlling the memory modules, the memory arrangement being configured in such a way that it forwards information routed by the memory controller to at least one of the memory modules to all memory modules, the memory controller being configured such that the memory controller divides information to be written to the memory arrangement into n data blocks of m bits each, and that the memory controller writes the n data blocks to the at least one memory module, wherein the at least one redundant memory module is configured such that each of the at least one redundant memory modules stores the n data blocks temporarily and calculates redundant information from the n data blocks and stores this, wherein the memory arrangement is configured such that the memory arrangement reads the n data blocks and checks for errors, p faulty data blocks thereof being detected, that the memory arrangement, if an error is present, determines all bits of the p faulty data blocks from the n data blocks and the redundant information, which the memory arrangement reads out in advance from the at least one redundant memory module in the event of an error, and that the memory arrangement outputs the n data blocks.

26. The memory arrangement according to claim 25, wherein the memory arrangement comprises at least two redundant memory modules, wherein at least one of the at least two redundant memory modules is configured such that it only stores a subset of the n data blocks temporarily, calculates redundant information from this subset and stores this.

27. The memory arrangement according to claim 25, wherein the memory arrangement comprises one redundant memory module, wherein the memory modules are connected to the memory controller in the form of a chain according to a daisy-chain principle, and wherein the redundant memory module is the last memory module in this chain.

28. The memory arrangement according to claim 25, wherein the memory arrangement comprises one redundant memory module, wherein the memory modules are connected in the form of a ring to the memory controller, and wherein the redundant memory module is arranged in the ring in such a way that it is furthest away from the memory controller.

29. A memory arrangement comprising:
at least one memory module;
one redundant memory module; and
a memory controller for controlling the memory modules, the memory arrangement configured in such a way that it forwards information routed by the memory controller to at least one of the memory modules to all memory modules, the memory controller being configured such that the memory controller divides information to be written to the memory arrangement into n data blocks of m bits each, and that the memory controller writes the n data blocks to the at least one memory module, wherein the redundant memory module is configured such that the redundant memory module stores the n data blocks temporarily and calculates redundant information from the n data blocks and stores this, wherein the memory arrangement is configured such that the memory arrangement reads the n data blocks and checks for errors, one faulty data block thereof being detected, that the memory arrangement, if an error is present, determines all bits of the faulty data block from the n data blocks and the redundant information, which the memory arrangement reads out in advance from the redundant memory module in the event of an error, and that the memory arrangement outputs the n data blocks.
